(19) United States
(12) Patent Application Publication
(10) Pub. No.: US 2016/0032454 A1
(43) Pub. Date: Feb. 4, 2016

(54) BIS(ALKYLIMIDO)-BIS(ALKYLAMIDO)TUNGSTEN MOLECULES FOR DEPOSITION OF TUNGSTEN-CONTAINING FILMS

(71) Applicant: L'AIR LIQUIDE, SOCIETE ANONYME POUR I'ETUDE ET I'EXPLOITATION DES PROCEDES GEORGES CLAUDE, Paris (FR)

(72) Inventors: Julien GATINEAU, Seoul (KR); Changhee KO, Tsukuba (JP); Jiro YOKOTA, Tsukuba (JP); Clément LANSALOT-MATRAS, Saint-Jammes (FR)

(21) Appl. No.: 14/775,140

(22) PCT Filed: Mar. 15, 2013
(86) PCT No.: PCT/IB2013/000930

§ 371 Date: Sep. 11, 2015

(51) Int. Cl. C23C 16/455; C23C 16/40; C23C 16/34

(52) U.S. Cl. CPC C23C 16/45553; C23C 16/45536; C23C 16/34; C23C 16/405

(57) ABSTRACT

Bis(alkylimido)-bis(alkylamido)tungsten compounds, their synthesis, and their use for the deposition of tungsten-containing films are disclosed.

### TECHNICAL FIELD

Bis(alkylimido)-bis(alkylamido)tungsten compounds, their synthesis, and their use for the deposition of W-containing films are disclosed.

### BACKGROUND ART

One of the goals for many semiconductor teams around the world is to be able to deposit WN films with low resistivity and excellent step coverage in high aspect ratios. Klaus et al. deposited tungsten nitride films with WF₆ and NH₃ as precursors in J. Electrochem. Soc. (2000 147 1175). However, reactive hydrogen halides may be released as by-products from this halide-ammonia systems.

Halide-free imido-amido metal-organic precursors having the general formula W(NR)₂(NR′₂)₂ have been introduced for tungsten nitride depositions. Becker et al., Chem. Mater. 2003, 15, 2969; Becker et al., Appl. Phys. Lett. 2003, 82, 2239; Correia-Anacleto et al., 8^{th} Intl Conference on Atomic Layer Deposition—ALD 2008, WedM2b-8; Atashi et al., Appl. Phys. Lett. 2007, 90, 173120; Tsai et al., Appl. Phys. Lett. 1996, 68, 1412.

Becker et al. disclose ALD deposition of WN using W(NtBu)₂(NMe₂)₂ and W(NtBu)₂(NMeEt)₂ precursors. Id. at Chem. Mater. and Appl. Phys. Lett. The emission of corrosive by-products may have been avoided by use of these precursors. However, the W(NtBu)₂(NMe₂)₂ precursors decomposed above 350° C., causing on-uniform deposition and poor film quality. Id.

Tsai et al. discloses CVD deposition of WN using W(NtBu)₂(NHtBu)₂. Id. at Appl. Phys. Lett.

Another goal is to be able to deposit WO films having higher K values and low leakage current.

A need remains for suitable tungsten precursors for vapor deposition of commercially suitable WN or WO films.

### Notation and Nomenclature

Certain abbreviations, symbols, and terms are used throughout the following description and claims, and include:

As used herein, the indefinite article “a” or “an” means one or more.

As used herein, the term “independently” when used in the context of describing R groups should be understood to denote that the subject R group is not only independently selected relative to other R groups bearing the same or different subscripts or superscripts, but is also independently selected relative to any additional species of that same R group. For example in the formula W(NR)₂(NHR′)₂, the four R groups may, but need not be identical to each other.

As used herein, the term “alkyl group” refers to saturated functional groups containing exclusively carbon and hydrogen atoms. Further, the term “alkyl group” refers to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the term “hydrocarbon” means a functional group containing exclusively hydrogen and carbon atoms. The functional group may be saturated (containing only single bonds) or unsaturated (containing double or triple bonds).

As used herein, the abbreviation “Me” refers to a methyl group; the abbreviation “Et” refers to an ethyl group; the abbreviation “Pr” refers to a n-propyl group; the abbreviation “iPr” refers to an isopropyl group; the abbreviation “Bu” refers to a n-butyl group; the abbreviation “tBu” refers to a tert-butyl group; the abbreviation “sBu” refers to a sec-butyl group; the abbreviation “iBu” refers to an iso-butyl group; and the abbreviation “tAmyl” refer to a tert-amyl group (also known as a pentyl group or C₅H₁₁).

The standard abbreviations of the elements from the periodic table of elements are used herein. It should be understood that elements may be referred to by these abbreviations (e.g., W refers to tungsten, N refers to nitrogen, H refers to hydrogen, etc.).

Please note that the W-containing films, such as WN, WCN, WSi, WSiN, and WO, are listed throughout the specification and claims without reference to their proper stoichiometry. The tungsten-containing layers resulting from the processes may include pure tungsten (W), tungsten nitride (WₖNₗ), tungsten carbide (WₖCₗ), tungsten carbonitride (WₖCₗNₘ), tungsten silicide (WₙSiₘ), or tungsten oxide (WₙOₘ) film, wherein k, l, m, and n inclusively range from 1 to 6. Preferably, tungsten nitride and tungsten carbide are WₖNₗ or (WₖCₗ), where k and l each range from 0.5 to 1.5. More preferably tungsten nitride is W₁N₁ and tungsten carbide is W₁C₁. Preferably tungsten oxide and tungsten silicide are WₙOₘ and WₙSiₘ, where n ranges from 0.5 to 1.5 and m ranges from 1.5 to 3.5. More preferably, tungsten oxide is WO₂ or WO₃ and tungsten silicide is WSi₂.

### SUMMARY OF INVENTION

Vapor deposition methods for forming tungsten-containing films on a substrate are disclosed. A tungsten-containing precursor is introduced into a vapor deposition chamber containing a substrate. Part or all of the tungsten-containing precursor is deposited on the substrate to form a tungsten-containing film. The tungsten-containing precursor has the formula W(NR)₂(NHR′)₂, wherein R and R′ are independently chosen from the group consisting of a C1-C4 alkyl group, a C1-C4 perfluoroalkyl group, and an alkylsilyl group. The disclosed methods may include one or more of the following aspects:
the tungsten-containing precursor being W(NMe)₂(NHMe)₂;
the tungsten-containing precursor being W(NMe)₂(NHEt)₂;
the tungsten-containing precursor being W(NMe)₂(NHPr)₂;
the tungsten-containing precursor being W(NMe)₂(NHiPr)₂;
the tungsten-containing precursor being W(NMe)₂(NHBu)₂;
the tungsten-containing precursor being W(NMe)₂(NHiBu)₂;
the tungsten-containing precursor being W(NMe)₂(NHsBu)₂;
the tungsten-containing precursor being W(NMe)₂(NHtBu)₂;
the tungsten-containing precursor being W(NEt)₂(NHMe)₂;
the tungsten-containing precursor being W(NEt)₂(NHEt)₂;
the tungsten-containing precursor being W(NEt)₂(NHPr)₂;
the tungsten-containing precursor being W(NEt)₂(NHiPr)₂;
the tungsten-containing precursor being W(NEt)₂(NHBu)₂;
the tungsten-containing precursor being W(NEt)₂(NHiBu)₂;
the tungsten-containing precursor being W(NEt)₂(NHsBu)₂;
the tungsten-containing precursor being W(NEt)₂(NHtBu)₂;
the tungsten-containing precursor being W(NPr)₂(NHMe)₂;
the tungsten-containing precursor being W(NPr)₂(NHEt)₂;
the tungsten-containing precursor being W(NPr)₂(NHPr)₂;
the tungsten-containing precursor being W(NPr)₂(NHiPr)₂;
the tungsten-containing precursor being W(NPr)₂(NHBu)₂;
the tungsten-containing precursor being W(NPr)₂(NHiBu)₂;
the tungsten-containing precursor being W(NPr)₂(NHsBu)₂;
the tungsten-containing precursor being W(NPr)₂(NHtBu)₂;
the tungsten-containing precursor being W(NiPr)₂(NHMe)₂;
the tungsten-containing precursor being W(NiPr)₂(NHEt)₂;
the tungsten-containing precursor being W(NiPr)₂(NHPr)₂;
the tungsten-containing precursor being W(NiPr)₂(NHiPr)₂;
the tungsten-containing precursor being W(NiPr)₂(NHBu)₂;
the tungsten-containing precursor being W(NiPr)₂(NHiBu)₂;
the tungsten-containing precursor being W(NiPr)₂(NHsBu)₂;
the tungsten-containing precursor being W(NiPr)₂(NHtBu)₂;
the tungsten-containing precursor being W(NBu)₂(NHMe)₂;
the tungsten-containing precursor being W(NBu)₂(NHEt)₂;
the tungsten-containing precursor being W(NBu)₂(NHPr)₂;
the tungsten-containing precursor being W(NBu)₂(NHiPr)₂;
the tungsten-containing precursor being W(NBu)₂(NHBu)₂;
the tungsten-containing precursor being W(NBu)₂(NHiBu)₂;
the tungsten-containing precursor being W(NBu)₂(NHsBu)₂;
the tungsten-containing precursor being W(NBu)₂(NHtBu)₂;
the tungsten-containing precursor being W(NiBu)₂(NHMe)₂;
the tungsten-containing precursor being W(NiBu)₂(NHEt)₂;
the tungsten-containing precursor being W(NiBu)₂(NHPr)₂;
the tungsten-containing precursor being W(NiBu)₂(NHiPr)₂;
the tungsten-containing precursor being W(NiBu)₂(NHBu)₂;
the tungsten-containing precursor being W(NiBu)₂(NHiBu)₂;
the tungsten-containing precursor being W(NiBu)₂(NHsBu)₂;
the tungsten-containing precursor being W(NiBu)₂(NHtBu)₂;
the tungsten-containing precursor being W(NsBu)₂(NHMe)₂;
the tungsten-containing precursor being W(NsBu)₂(NHEt)₂;
the tungsten-containing precursor being W(NsBu)₂(NHPr)₂;
the tungsten-containing precursor being W(NsBu)₂(NHiPr)₂;
the tungsten-containing precursor being W(NsBu)₂(NHBu)₂;
the tungsten-containing precursor being W(NsBu)₂(NHiBu)₂;
the tungsten-containing precursor being W(NsBu)₂(NHsBu)₂;
the tungsten-containing precursor being W(NsBu)₂(NHtBu)₂;
the tungsten-containing precursor being W(NtBu)₂(NHMe)₂;
the tungsten-containing precursor being W(NtBu)₂(NHEt)₂;
the tungsten-containing precursor being W(NtBu)₂(NHPr)₂;
the tungsten-containing precursor being W(NtBu)₂(NHiPr)₂;
the tungsten-containing precursor being W(NtBu)₂(NHBu)₂;
the tungsten-containing precursor being W(NtBu)₂(NHiBu)₂;
the tungsten-containing precursor being W(NtBu)₂(NHsBu)₂;
the tungsten-containing precursor being W(NtBu)₂(NHtBu)₂;
the tungsten-containing precursor being W(NSiMe₃)₂(NHMe)₂;
the tungsten-containing precursor being W(NSiMe₃)₂(NHEt)₂;
the tungsten-containing precursor being W(NSiMe₃)₂(NHPr)₂;
the tungsten-containing precursor being W(NSiMe₃)₂(NHiPr)₂;
the tungsten-containing precursor being W(NSiMe₃)₂(NHBu)₂;
the tungsten-containing precursor being W(NSiMe₃)₂(NHiBu)₂;
the tungsten-containing precursor being W(NSiMe₃)₂(NHsBu)₂;
the tungsten-containing precursor being W(NSiMe₃)₂(NHtBu)₂;
the tungsten-containing precursor being W(NCF₃)₂(NHMe)₂;
the tungsten-containing precursor being W(NCF₃)₂(NHEt)₂;
the tungsten-containing precursor being W(NCF₃)₂(NHPr)₂;
the tungsten-containing precursor being W(NCF₃)₂(NHiPr)₂;
the tungsten-containing precursor being W(NCF₃)₂(NHBu)₂;
the tungsten-containing precursor being W(NCF₃)₂(NHiBu)₂;
the tungsten-containing precursor being W(NCF₃)₂(NHsBu)₂;
the tungsten-containing precursor being W(NCF₃)₂(NHtBu)₂;
the tungsten-containing precursor being W(NMe)₂(NHSiMe₃)₂;
the tungsten-containing precursor being W(NEt)₂(NHSiMe₃)₂;
the tungsten-containing precursor being W(NPr)₂(NHSiMe₃)₂;
the tungsten-containing precursor being W(NtBu)₂(NHSiMe₃)₂;
the tungsten-containing precursor being W(NtAmyl)₂(NHMe)₂;
the tungsten-containing precursor being W(NtAmyl)₂(NHEt)₂;
the tungsten-containing precursor being W(NtAmyl)₂(NHPr)₂;
the tungsten-containing precursor being W(NtAmyl)₂(NHiPr)₂;
the tungsten-containing precursor being W(NtAmyl)₂(NHBu)₂;
the tungsten-containing precursor being W(NtAmyl)₂(NHiBu)₂;
the tungsten-containing precursor being W(NtAmyl)₂(NHsBu)₂;
the tungsten-containing precursor being W(NtAmyl)₂(NHtBu)₂;
the tungsten-containing precursor being W(NtAmyl)₂(NHSiMe₃)₂;
the tungsten-containing precursor being W(NtBu)(NtAmyl)(NHtBu)₂;
the vapor deposition method being ALD;
the vapor deposition method being PE-ALD;
the vapor deposition method being spatial ALD;
the vapor deposition method being CVD;
the vapor deposition method being PE-CVD;
at least part of the tungsten-containing precursor being deposited on the substrate by plasma enhanced atomic layer deposition;
a plasma power is between about 30 W and about 600 W;
a plasma power is between about 100 W and about 500 W;
reacting the tungsten-containing precursor with a reducing agent;
the reducing agent being selected from the group consisting of N₂, H₂, NH₃, N₂H₄ and any hydrazine based compounds, SiH₄, Si₂H₆, radical species thereof, and combinations thereof;
reacting the at least part of the tungsten-containing precursor with an oxidizing agent;
the oxidizing agent being selected from the group consisting of O₂, H₂O, O₃, H₂O₂, N₂O, NO, acetic acid, the radical species thereof, and combinations thereof;
performing the method at a pressure between about 0.01 Pa and about 1×10⁵ Pa;
performing the method at a pressure between about 0.1 Pa and about 1×10⁴ Pa;
performing the method at a temperature between about 20° C. and about 500° C.;
performing the method at a temperature between about 350° C. and about 500° C.;
the tungsten-containing film being W;
the tungsten-containing film being WO;
the tungsten-containing film being WN;
the tungsten-containing film being WSi;
the tungsten-containing film being WSiN; and
the tungsten-containing film being WCN.

Chemical vapor deposition methods for forming tungsten-containing films on a substrate are also disclosed. A tungsten-containing precursor is introduced into a vapor deposition chamber containing a substrate. At least part of the tungsten-containing precursor reacts with an oxidizing agent at the surface of the substrate to form a tungsten-containing film. The tungsten-containing precursor has the formula W(NR)₂(NHR′)₂, wherein R and R′ are independently chosen from the group consisting of a C1-C4 alkyl group, a C1-C4 perfluoroalkyl group, and an alkylsilyl group. The disclosed methods may include one or more of the following aspects:
the tungsten-containing precursor being W(NMe)₂(NHMe)₂;
the tungsten-containing precursor being W(NMe)₂(NHEt)₂;
the tungsten-containing precursor being W(NMe)₂(NHPr)₂;
the tungsten-containing precursor being W(NMe)₂(NHiPr)₂;
the tungsten-containing precursor being W(NMe)₂(NHBu)₂;
the tungsten-containing precursor being W(NMe)₂(NHiBu)₂;
the tungsten-containing precursor being W(NMe)₂(NHsBu)₂;
the tungsten-containing precursor being W(NMe)₂(NHtBu)₂;
the tungsten-containing precursor being W(NEt)₂(NHMe)₂;
the tungsten-containing precursor being W(NEt)₂(NHEt)₂;
the tungsten-containing precursor being W(NEt)₂(NHPr)₂;
the tungsten-containing precursor being W(NEt)₂(NHiPr)₂;
the tungsten-containing precursor being W(NEt)₂(NHBu)₂;
the tungsten-containing precursor being W(NEt)₂(NHiBu)₂;
the tungsten-containing precursor being W(NEt)₂(NHsBu)₂;
the tungsten-containing precursor being W(NEt)₂(NHtBu)₂;
the tungsten-containing precursor being W(NPr)₂(NHMe)₂;
the tungsten-containing precursor being W(NPr)₂(NHEt)₂;
the tungsten-containing precursor being W(NPr)₂(NHPr)₂;
the tungsten-containing precursor being W(NPr)₂(NHiPr)₂;
the tungsten-containing precursor being W(NPr)₂(NHBu)₂;
the tungsten-containing precursor being W(NPr)₂(NHiBu)₂;
the tungsten-containing precursor being W(NPr)₂(NHsBu)₂;
the tungsten-containing precursor being W(NPr)₂(NHtBu)₂;
the tungsten-containing precursor being W(NiPr)₂(NHMe)₂;
the tungsten-containing precursor being W(NiPr)₂(NHEt)₂;
the tungsten-containing precursor being W(NiPr)₂(NHPr)₂;
the tungsten-containing precursor being W(NiPr)₂(NHiPr)₂;
the tungsten-containing precursor being W(NiPr)₂(NHBu)₂;
the tungsten-containing precursor being W(NiPr)₂(NHiBu)₂;
the tungsten-containing precursor being W(NiPr)₂(NHsBu)₂;
the tungsten-containing precursor being W(NiPr)₂(NHtBu)₂;
the tungsten-containing precursor being W(NBu)₂(NHMe)₂;
the tungsten-containing precursor being W(NBu)₂(NHEt)₂;
the tungsten-containing precursor being W(NBu)₂(NHPr)₂;
the tungsten-containing precursor being W(NBu)₂(NHiPr)₂;
the tungsten-containing precursor being W(NBu)₂(NHBu)₂;
the tungsten-containing precursor being W(NBu)₂(NHiBu)₂;
the tungsten-containing precursor being W(NBu)₂(NHsBu)₂;
the tungsten-containing precursor being W(NBu)₂(NHtBu)₂;
the tungsten-containing precursor being W(NiBu)₂(NHMe)₂;
the tungsten-containing precursor being W(NiBu)₂(NHEt)₂;
the tungsten-containing precursor being W(NiBu)₂(NHPr)₂;
the tungsten-containing precursor being W(NiBu)₂(NHiPr)₂;
the tungsten-containing precursor being W(NiBu)₂(NHBu)₂;
the tungsten-containing precursor being W(NiBu)₂(NHiBu)₂;
the tungsten-containing precursor being W(NiBu)₂(NHsBu)₂;
the tungsten-containing precursor being W(NiBu)₂(NHtBu)₂;
the tungsten-containing precursor being W(NsBu)₂(NHMe)₂;
the tungsten-containing precursor being W(NsBu)₂(NHEt)₂;
the tungsten-containing precursor being W(NsBu)₂(NHPr)₂;
the tungsten-containing precursor being W(NsBu)₂(NHiPr)₂;
the tungsten-containing precursor being W(NsBu)₂(NHBu)₂;
the tungsten-containing precursor being W(NsBu)₂(NHiBu)₂;
the tungsten-containing precursor being W(NsBu)₂(NHsBu)₂;
the tungsten-containing precursor being W(NsBu)₂(NHtBu)₂;
the tungsten-containing precursor being W(NtBu)₂(NHMe)₂;
the tungsten-containing precursor being W(NtBu)₂(NHEt)₂;
the tungsten-containing precursor being W(NtBu)₂(NHPr)₂;
the tungsten-containing precursor being W(NtBu)₂(NHiPr)₂;
the tungsten-containing precursor being W(NtBu)₂(NHBu)₂;
the tungsten-containing precursor being W(NtBu)₂(NHiBu)₂;
the tungsten-containing precursor being W(NtBu)₂(NHsBu)₂;
the tungsten-containing precursor being W(NtBu)₂(NHtBu)₂;
the tungsten-containing precursor being W(NSiMe₃)₂(NHMe)₂;
the tungsten-containing precursor being W(NSiMe₃)₂(NHEt)₂;
the tungsten-containing precursor being W(NSiMe₃)₂(NHPr)₂;
the tungsten-containing precursor being W(NSiMe₃)₂(NHiPr)₂;
the tungsten-containing precursor being W(NSiMe₃)₂(NHBu)₂;
the tungsten-containing precursor being W(NSiMe₃)₂(NHiBu)₂;
the tungsten-containing precursor being W(NSiMe₃)₂(NHsBu)₂;
the tungsten-containing precursor being W(NSiMe₃)₂(NHtBu)₂;
the tungsten-containing precursor being W(NCF₃)₂(NHMe)₂;
the tungsten-containing precursor being W(NCF₃)₂(NHEt)₂;
the tungsten-containing precursor being W(NCF₃)₂(NHPr)₂;
the tungsten-containing precursor being W(NCF₃)₂(NHiPr)₂;
the tungsten-containing precursor being W(NCF₃)₂(NHBu)₂;
the tungsten-containing precursor being W(NCF₃)₂(NHiBu)₂;
the tungsten-containing precursor being W(NCF₃)₂(NHsBu)₂;
the tungsten-containing precursor being W(NCF₃)₂(NHtBu)₂;
the tungsten-containing precursor being W(NMe)₂(NHSiMe₃)₂;
the tungsten-containing precursor being W(NEt)₂(NHSiMe₃)₂;
the tungsten-containing precursor being W(NPr)₂(NHSiMe₃)₂;
the tungsten-containing precursor being W(NtBu)₂(NHSiMe₃)₂;
the tungsten-containing precursor being W(NMe)₂(NHSiMe₃)₂;
the tungsten-containing precursor being W(NEt)₂(NHSiMe₃)₂;
the tungsten-containing precursor being W(NPr)₂(NHSiMe₃)₂;
the tungsten-containing precursor being W(NtBu)₂(NHSiMe₃)₂;
the tungsten-containing precursor being W(NtAmyl)₂(NHMe)₂;
the tungsten-containing precursor being W(NtAmyl)₂(NHEt)₂;
the tungsten-containing precursor being W(NtAmyl)₂(NHPr)₂;
the tungsten-containing precursor being W(NtAmyl)₂(NHiPr)₂;
the tungsten-containing precursor being W(NtAmyl)₂(NHBu)₂;
the tungsten-containing precursor being W(NtAmyl)₂(NHiBu)₂;
the tungsten-containing precursor being W(NtAmyl)₂(NHsBu)₂;
the tungsten-containing precursor being W(NtAmyl)₂(NHtBu)₂;
the tungsten-containing precursor being W(NtAmyl)₂(NHSiMe₃)₂;
the tungsten-containing precursor being W(NtBu)(NtAmyl)(NHtBu)₂;
the chemical vapor deposition method being plasma enhanced chemical vapor deposition;
a plasma power is between about 30 W and about 600 W;
a plasma power is between about 100 W and about 500 W;
the oxidizing agent being selected from the group consisting of O₂, H₂O, O₃, H₂O₂, N₂O, NO, acetic acid, the radical species thereof, and combinations thereof;
performing the method at a pressure between about 0.01 Pa and about 1×10⁵ Pa;
performing the method at a pressure between about 0.1 Pa and about 1×10⁴ Pa;
performing the method at a temperature between about 20° C. and about 500° C.; and
performing the method at a temperature between about 350° C. and about 500° C.

Also disclosed are atomic layer deposition methods for forming tungsten-containing films on a substrate. A tungsten-containing precursor is introduced into a vapor deposition chamber containing a substrate. Part or all of the tungsten-containing precursor is deposited on the substrate by atomic layer deposition to form a tungsten-containing film. The tungsten-containing precursor has the formula W(NR)₂(NHR′)₂, wherein R and R′ are independently chosen from the group consisting of a C1-C4 alkyl group, a C1-C4 perfluoroalkyl group, and an alkylsilyl group. The disclosed methods may include one or more of the following aspects:
the tungsten-containing precursor being W(NMe)₂(NHMe)₂;
the tungsten-containing precursor being W(NMe)₂(NHEt)₂;
the tungsten-containing precursor being W(NMe)₂(NHPr)₂;
the tungsten-containing precursor being W(NMe)₂(NHiPr)₂;
the tungsten-containing precursor being W(NMe)₂(NHBu)₂;
the tungsten-containing precursor being W(NMe)₂(NHiBu)₂;
the tungsten-containing precursor being W(NMe)₂(NHsBu)₂;
the tungsten-containing precursor being W(NMe)₂(NHtBu)₂;
the tungsten-containing precursor being W(NEt)₂(NHMe)₂;
the tungsten-containing precursor being W(NEt)₂(NHEt)₂;
the tungsten-containing precursor being W(NEt)₂(NHPr)₂;
the tungsten-containing precursor being W(NEt)₂(NHiPr)₂;
the tungsten-containing precursor being W(NEt)₂(NHBu)₂;
the tungsten-containing precursor being W(NEt)₂(NHiBu)₂;
the tungsten-containing precursor being W(NEt)₂(NHsBu)₂;
the tungsten-containing precursor being W(NEt)₂(NHtBu)₂;
the tungsten-containing precursor being W(NPr)₂(NHMe)₂;
the tungsten-containing precursor being W(NPr)₂(NHEt)₂;
the tungsten-containing precursor being W(NPr)₂(NHPr)₂;
the tungsten-containing precursor being W(NPr)₂(NHiPr)₂;
the tungsten-containing precursor being W(NPr)₂(NHBu)₂;
the tungsten-containing precursor being W(NPr)₂(NHiBu)₂;
the tungsten-containing precursor being W(NPr)₂(NHsBu)₂;
the tungsten-containing precursor being W(NPr)₂(NHtBu)₂;
the tungsten-containing precursor being W(NiPr)₂(NHMe)₂;
the tungsten-containing precursor being W(NiPr)₂(NHEt)₂;
the tungsten-containing precursor being W(NiPr)₂(NHPr)₂;
the tungsten-containing precursor being W(NiPr)₂(NHiPr)₂;
the tungsten-containing precursor being W(NiPr)₂(NHBu)₂;
the tungsten-containing precursor being W(NiPr)₂(NHiBu)₂;
the tungsten-containing precursor being W(NiPr)₂(NHsBu)₂;
the tungsten-containing precursor being W(NiPr)₂(NHtBu)₂;
the tungsten-containing precursor being W(NBu)₂(NHMe)₂;
the tungsten-containing precursor being W(NBu)₂(NHEt)₂;
the tungsten-containing precursor being W(NBu)₂(NHPr)₂;
the tungsten-containing precursor being W(NBu)₂(NHiPr)₂;
the tungsten-containing precursor being W(NBu)₂(NHBu)₂;
the tungsten-containing precursor being W(NBu)₂(NHiBu)₂;
the tungsten-containing precursor being W(NBu)₂(NHsBu)₂;
the tungsten-containing precursor being W(NBu)₂(NHtBu)₂;
the tungsten-containing precursor being W(NiBu)₂(NHMe)₂;
the tungsten-containing precursor being W(NiBu)₂(NHEt)₂;
the tungsten-containing precursor being W(NiBu)₂(NHPr)₂;
the tungsten-containing precursor being W(NiBu)₂(NHiPr)₂;
the tungsten-containing precursor being W(NiBu)₂(NHBu)₂;
the tungsten-containing precursor being W(NiBu)₂(NHiBu)₂;
the tungsten-containing precursor being W(NiBu)₂(NHsBu)₂;
the tungsten-containing precursor being W(NiBu)₂(NHtBu)₂;
the tungsten-containing precursor being W(NsBu)₂(NHMe)₂;
the tungsten-containing precursor being W(NsBu)₂(NHEt)₂;
the tungsten-containing precursor being W(NsBu)₂(NHPr)₂;
the tungsten-containing precursor being W(NsBu)₂(NHiPr)₂;
the tungsten-containing precursor being W(NsBu)₂(NHBu)₂;
the tungsten-containing precursor being W(NsBu)₂(NHiBu)₂;
the tungsten-containing precursor being W(NsBu)₂(NHsBu)₂;
the tungsten-containing precursor being W(NsBu)₂(NHtBu)₂;
the tungsten-containing precursor being W(NtBu)₂(NHMe)₂;
the tungsten-containing precursor being W(NtBu)₂(NHEt)₂;
the tungsten-containing precursor being W(NtBu)₂(NHPr)₂;
the tungsten-containing precursor being W(NtBu)₂(NHiPr)₂;
the tungsten-containing precursor being W(NtBu)₂(NHBu)₂;
the tungsten-containing precursor being W(NtBu)₂(NHiBu)₂;
the tungsten-containing precursor being W(NtBu)₂(NHsBu)₂;
the tungsten-containing precursor being W(NtBu)₂(NHtBu)₂;
the tungsten-containing precursor being W(NSiMe₃)₂(NHMe)₂;
the tungsten-containing precursor being W(NSiMe₃)₂(NHEt)₂;
the tungsten-containing precursor being W(NSiMe₃)₂(NHPr)₂;
the tungsten-containing precursor being W(NSiMe₃)₂(NHiPr)₂;
the tungsten-containing precursor being W(NSiMe₃)₂(NHBu)₂;
the tungsten-containing precursor being W(NSiMe₃)₂(NHiBu)₂;
the tungsten-containing precursor being W(NSiMe₃)₂(NHsBu)₂;
the tungsten-containing precursor being W(NSiMe₃)₂(NHtBu)₂;
the tungsten-containing precursor being W(NCF₃)₂(NHMe)₂;
the tungsten-containing precursor being W(NCF₃)₂(NHEt)₂;
the tungsten-containing precursor being W(NCF₃)₂(NHPr)₂;
the tungsten-containing precursor being W(NCF₃)₂(NHiPr)₂;
the tungsten-containing precursor being W(NCF₃)₂(NHBu)₂;
the tungsten-containing precursor being W(NCF₃)₂(NHiBu)₂;
the tungsten-containing precursor being W(NCF₃)₂(NHsBu)₂;
the tungsten-containing precursor being W(NCF₃)₂(NHtBu)₂;
the tungsten-containing precursor being W(NMe)₂(NHSiMe₃)₂;
the tungsten-containing precursor being W(NEt)₂(NHSiMe₃)₂;
the tungsten-containing precursor being W(NPr)₂(NHSiMe₃)₂;
the tungsten-containing precursor being W(NtBu)₂(NHSiMe₃)₂;
the tungsten-containing precursor being W(NMe)₂(NHSiMe₃)₂;
the tungsten-containing precursor being W(NEt)₂(NHSiMe₃)₂;
the tungsten-containing precursor being W(NPr)₂(NHSiMe₃)₂;
the tungsten-containing precursor being W(NtBu)₂(NHSiMe₃)₂;
the tungsten-containing precursor being W(NtAmyl)₂(NHMe)₂;
the tungsten-containing precursor being W(NtAmyl)₂(NHEt)₂;
the tungsten-containing precursor being W(NtAmyl)₂(NHPr)₂;
the tungsten-containing precursor being W(NtAmyl)₂(NHiPr)₂;
the tungsten-containing precursor being W(NtAmyl)₂(NHBu)₂;
the tungsten-containing precursor being W(NtAmyl)₂(NHiBu)₂;
the tungsten-containing precursor being W(NtAmyl)₂(NHsBu)₂;
the tungsten-containing precursor being W(NtAmyl)₂(NHtBu)₂;
the tungsten-containing precursor being W(NtAmyl)₂(NHSiMe₃)₂;
the tungsten-containing precursor being W(NtBu)(NtAmyl)(NHtBu)₂;
at least part of the tungsten-containing precursor being deposited on the substrate by plasma enhanced atomic layer deposition;
a plasma power is between about 30 W and about 600 W;
a plasma power is between about 100 W and about 500 W;
reacting the tungsten-containing precursor with a reducing agent;
the reducing agent being selected from the group consisting of N₂, H₂, NH₃, N₂H₄ and any hydrazine based compounds, SiH₄, Si₂H₆, radical species thereof, and combinations thereof;
reacting the at least part of the tungsten-containing precursor with an oxidizing agent;
the oxidizing agent being selected from the group consisting of O₂, H₂O, O₃, H₂O₂, N₂O, NO, acetic acid, the radical species thereof, and combinations thereof;
performing the method at a pressure between about 0.01 Pa and about 1×10⁵ Pa;
performing the method at a pressure between about 0.1 Pa and about 1×10⁴ Pa;
performing the method at a temperature between about 20° C. and about 500° C.;
performing the method at a temperature between about 350° C. and about 500° C.;
the tungsten-containing film being W;
the tungsten-containing film being WO;
the tungsten-containing film being WN;
the tungsten-containing film being WSi;
the tungsten-containing film being WSiN; and
the tungsten-containing film being WCN.

### BRIEF DESCRIPTION OF DRAWINGS

For a further understanding of the nature and objects of the present invention, reference should be made to the following detailed description, taken in conjunction with the accompanying FIG, and wherein:

FIG. 1 is a figure illustrating the benefit of including H in the NHR′ amido ligand of the disclosed tungsten compounds.

FIG. 2 is a thermogravimetric analysis graph comparing the percentage mass loss with increasing temperature for bis(tertbutylimido)bis(dimethylamido)tungsten (BTBDMW) and bis(tertbutylimido)bis(tertbutylamido)tungsten (BTBTTW).

### DESCRIPTION OF EMBODIMENTS

Bis(alkylimido)-bis(alkylamido)tungsten compounds are disclosed. The bis(alkylimido)-bis(alkylamido)tungsten compounds have the formula W(NR)₂(NHR′)₂, wherein R and R′ are independently chosen from the group consisting of a C1-C4 alkyl group, a C1-04 perfluoroalkyl group, and an alkylsilyl group.

Exemplary bis(alkylimido)-bis(alkylamido)tungsten compounds include W(NMe)₂(NHMe)₂, W(NMe)₂(NHEt)₂, W(NMe)₂(NHPr)₂, W(NMe)₂(NHiPr)₂, W(NMe)₂(NHBu)₂, W(NMe)₂(NHiBu)₂, W(NMe)₂(NHsBu)₂, W(NMe)₂(NHtBu)₂, W(NEt)₂(NHMe)₂, W(NEt)₂(NHEt)₂, W(NEt)₂(NHPr)₂, W(NEt)₂(NHiPr)₂, W(NEt)₂(NHBu)₂, W(NEt)₂(NHiBu)₂, W(NEt)₂(NHsBu)₂, W(NEt)₂(NHtBu)₂, W(NPr)₂(NHMe)₂, W(NPr)₂(NHEt)₂, W(NPr)₂(NHPr)₂, W(NPr)₂(NHiPr)₂, W(NPr)₂(NHBu)₂, W(NPr)₂(NHiBu)₂, W(NPr)₂(NHsBu)₂, W(NPr)₂(NHtBu)₂, W(NiPr)₂(NHMe)₂, W(NiPr)₂(NHEt)₂, W(NiPr)₂(NHPr)₂, W(NiPr)₂(NHiPr)₂, W(NiPr)₂(NHBu)₂, W(NiPr)₂(NHiBu)₂, W(NiPr)₂(NHsBu)₂, W(NiPr)₂(NHtBu)₂, W(NBu)₂(NHMe)₂, W(NBu)₂(NHEt)₂, W(NBu)₂(NHPr)₂, W(NBu)₂(NHiPr)₂, W(NBu)₂(NHBu)₂, W(NBu)₂(NHiBu)₂, W(NBu)₂(NHsBu)₂, W(NBu)₂(NHtBu)₂, W(NiBu)₂(NHMe)₂, W(NiBu)₂(NHEt)₂, W(NiBu)₂(NHPr)₂, W(NiBu)₂(NHiPr)₂, W(NiBu)₂(NHBu)₂, W(NiBu)₂(NHiBu)₂, W(NiBu)₂(NHsecBu)₂, W(NiBu)₂(NHtBu)₂, W(NsBu)₂(NHMe)₂, W(NsBu)₂(NHEt)₂, W(NsBu)₂(NHPr)₂, W(NsBu)₂(NHiPr)₂, W(NsBu)₂(NHBu)₂, W(NsBu)₂(NHiBu)₂, W(NsBu)₂(NHsBu)₂, W(NsBu)₂(NHtBu)₂, W(NtBu)₂(NHMe)₂, W(NtBu)₂(NHEt)₂, W(NtBu)₂(NHPr)₂, W(NtBu)₂(NHiPr)₂, W(NtBu)₂(NHBu)₂, W(NtBu)₂(NHiBu)₂, W(NtBu)₂(NHsBu)₂, W(NtBu)₂(NHtBu)₂, W(NSiMe₃)₂(NHMe)₂, W(NSiMe₃)₂(NHEt)₂, W(NSiMe₃)₂(NHPr)₂, W(NSiMe₃)₂(NHiPr)₂, W(NSiMe₃)₂(NHBu)₂, W(NSiMe₃)₂(NHiBu)₂, W(NSiMe₃)₂(NHsBu)₂, W(NSiMe₃)₂(NHtBu)₂, W(NCF₃)₂(NHMe)₂, W(NCF₃)₂(NHEt)₂, W(NCF₃)₂(NHPr)₂, W(NCF₃)₂(NHiPr)₂, W(NCF₃)₂(NHBu)₂, W(NCF₃)₂(NHiBu)₂, W(NCF₃)₂(NHsBu)₂, W(NCF₃)₂(NHtBu)₂, W(NMe)₂(NHSiMe₃)₂, W(NEt)₂(NHSiMe₃)₂, W(NPr)₂(NHSiMe₃)₂, W(NtBu)₂(NHSiMe₃)₂, W(NtAmyl)₂(NHMe)₂, W(NtAmyl)₂(NHEt)₂, W(NtAmyl)₂(NHPr)₂, W(NtAmyl)₂(NHiPr)₂, W(NtAmyl)₂(NHBu)₂, W(NtAmyl)₂(NHiBu)₂, W(NtAmyl)₂(NHsBu)₂, W(NtAmyl)₂(NHtBu)₂, W(NtAmyl)₂(NHSiMe₃)₂, and W(NtAmyl)(NtBu)(NHtBu)₂, preferably W(NtBu)₂(NHiPr)₂, W(NtBu)₂(NHtBu)₂, W(NtAmyl)₂(NHiPr)₂, or W(NtAmyl)₂(NHtBu)₂.

The Bis(alkylimido)-bis(alkylamido) tungsten compounds may be synthesized by the method described by R.L. Harlow, Inorganic Chemistry, 1980, 19, 777, and W.A. Nugent, Inorganic Chemistry, 1983, 22, 965, with minor modifications obvious to one of ordinary skill in the art (e.g., WO₂Cl₂→adducted W(NR)₂Cl₂→W(NR)₂(NHR′)₂). The final product may be prepared under reaction with an excess amount of LiNHR′. The perfluoroalkyl- and alkylsilyl-containing bis(alkylimido)-bis(alkylamido) tungsten compounds may also be prepared using the same synthesis routes.

Vapor deposition methods of depositing tungsten-containing films from the bis(alkylimido)-bis(alkylamido)tungsten compounds are also disclosed. The bis(alkylimido)-bis(alkylamido)tungsten compound is introduced into a reactor having a substrate disposed therein. At least part of the bis(alkylimido)-bis(alkylamido)tungsten compound is deposited onto the substrate to form the tungsten-containing film.

Applicants believe that inclusion of hydrogen in the amido group (i.e., NHR′) will provide a faster ALD growth rate, a higher ALD temperature window, and lower impurity concentrations in the resulting films when compared to films deposited by analogous di-alkyl amido groups (i.e., NR₂). A faster growth rate is a key advantage because it allows higher throughput in the industrial deposition tools (e.g., processing more wafers per hour), provided the resulting layer has similar or better electrical performance.

The ALD temperature window and impurity concentrations are related to a certain extent. The higher thermal stability of the disclosed molecules allows deposition in ALD mode at higher temperatures when compared to the thermal stability and ALD temperature window of the analogous di-alkyl amido groups. Deposition at higher temperatures may increase the reactivity of the reducing agent, resulting in better film density and lower C and O concentrations for WN films and lower C and N concentrations for WO films. The higher density of the WN film will increase the barrier properties of the film. For deposition of WO films, the higher ALD temperature window allows for deposition of a better crystallographic phase, which provides higher K values.

The resistivity of the WN film is impacted by the concentration of any impurities in the film, such as C or O. Higher C concentrations may suggest decomposition of the bis(alkylimido)-bis(alkylamido)tungsten compound (i.e., thermal instability of the compound). Resistivity and barrier properties of the WN films have a direct impact on the chip efficiency (RC delay, electromigration, reliability). Higher C and N concentrations in the WO films may increase leakage current of the film. As a result, Applicants believe they have surprisingly discovered an improved ALD deposition process using the disclosed precursors for WN films. For the reasons described above, one of ordinary skill in the art would expect similar results using the disclosed precursors in the deposition of pure tungsten, tungsten silicide (WSi), tungsten silicide nitride (WSiN) films, and tungsten oxide (WO) films.

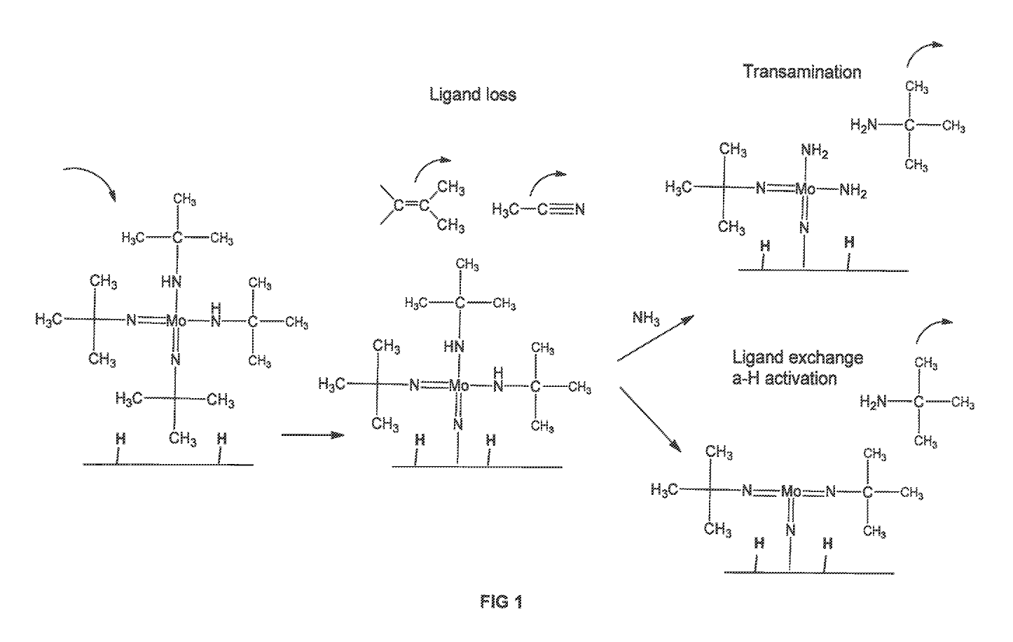

Applicants believe that hydrogen in the amido group (i.e., NHR′) is critical to the stability of the chemisorped species. Applicants further believe that the bulky tBu amido groups offer a great advantage by fully occupying the space around the metal in a symmetrical fashion with the tBu imido group. This may be the result of delocalization of the double bond in between the amido and imido groups. As reported by Correia-Anacleto et al., the ALD mechanism may take place through the imido group (i.e., NR) (8^{th} Intl Conference on Atomic Layer Deposition—ALD 2008, WedM2b-8). Applicants believe the inclusion of H in the amido group renders the amido ligand more acidic than the analogous dialkyl amido group. The acidity of the NHR′ group may make the amido group more reactive to the reducing or oxidizing agent. The acidity of the NHR′ may further make the amido group less reactive to the substrate surface. As a result, the chemisorped W species remains in contact with the substrate for a longer time period, permitting the species to react through ligand exchange by α-H activation and either transamination with the reducing agent or oxidation with the oxidizing agent. See FIG. 1. Applicants believe that both of these reactions produce faster ALD growth rate and a higher ALD temperature window. As a result, ALD deposition using the class of disclosed molecules will provide better films compared to those of the analogous dialkyl compounds.

At least part of the disclosed bis(alkylimido)-bis(alkylamido) tungsten compounds may deposited onto a substrate to form the tungsten-containing films by chemical vapor deposition (CVD), atomic layer deposition (ALD), or other types of depositions that are related to vapor coating such as a plasma enhanced CVD (PECVD), plasma enhanced ALD (PEALD), pulsed CVD (PCVD), low pressure CVD (LPCVD), sub-atmospheric CVD (SACVD) or atmospheric pressure CVD (APCVD), hot-wire CVD (HWCVD, also known as cat-CVD, in which a hot wire serves as an energy source for the deposition process), spatial ALD, hot-wire ALD (HWALD), radicals incorporated deposition, and super critical fluid deposition or combinations thereof. The deposition method is preferably ALD, PE-ALD, or spatial ALD in order to provide suitable step coverage and film thickness control.

The disclosed methods may be useful in the manufacture of semiconductor, photovoltaic, LCD-TFT, or flat panel type devices. The method includes introducing the vapor of at least one bis(alkylimido)-bis(alkylamido)tungsten compound disclosed above into a reactor having at least one substrate disposed therein and depositing at least part of the bis(alkylimido)-bis(alkylamido)tungsten compound onto the at least one substrate to form a tungsten-containing layer using a vapor deposition process. The temperature and the pressure within the reactor and the temperature of the substrate are held at conditions suitable for formation of the W-containing layer on at least one surface of the substrate. A reaction gas may also be used to help in formation of the W-containing layer.

The disclosed methods may also be used to form a two metal-containing layer on a substrate using a vapor deposition process and, more particularly, for deposition of WMO_{X} layers, wherein M is the second element and is selected from the group consisting of group 2, group 3, group 4, group 5, group 13, group 14, transition metal, lanthanides, and combinations thereof, and more preferably from Mg, Ca, Sr, Ba, Hf, Nb, Ta, Al, Si, Ge, Y, or lanthanides. The method includes: introducing at least one bis(alkylimido)-bis(alkylamido)tungsten compound disclosed above into a reactor having at least one substrate disposed therein, introducing a second precursor into the reactor, and depositing at least part of the bis(alkylimido)-bis(alkylamido)tungsten compound and at least part of the second precursor onto the at least one substrate to form the two element-containing layer using a vapor deposition process.

The reactor may be any enclosure or chamber of a device in which deposition methods take place, such as, without limitation, a parallel-plate type reactor, a cold-wall type reactor, a hot-wall type reactor, a single-wafer reactor, a multi-wafer reactor, or other such types of deposition systems. All of these exemplary reactors are capable of serving as an ALD or CVD reactor. The reactor may be maintained at a pressure ranging from about 0.01 Pa to about 1×10⁵ Pa, preferably from about 0.1 Pa to about 1×10⁴ Pa. In addition, the temperature within the reactor may range from about room temperature (20° C.) to about 500° C., preferably from about 350° C. to about 500° C. One of ordinary skill in the art will recognize that the temperature may be optimized through mere experimentation to achieve the desired result.

The temperature of the reactor may be controlled by either controlling the temperature of the substrate holder (called a cold wall reactor) or controlling the temperature of the reactor wall (called a hot wall reactor) or a combination of both methods. Devices used to heat the substrate are known in the art.

The reactor wall may be heated to a sufficient temperature to obtain the desired film at a sufficient growth rate and with desired physical state and composition. A non-limiting exemplary temperature range to which the reactor wall may be heated includes from approximately 20° C. to approximately 500° C. When a plasma deposition process is utilized, the deposition temperature may range from approximately 20° C. to approximately 500° C. Alternatively, when a thermal process is performed, the deposition temperature may range from approximately 100° C. to approximately 500° C.

Alternatively, the substrate may be heated to a sufficient temperature to obtain the desired tungsten-containing layer at a sufficient growth rate and with desired physical state and composition. A non-limiting exemplary temperature range to which the substrate may be heated includes from 100° C. to 500° C. Preferably, the temperature of the substrate remains less than or equal to 500° C.

The type of substrate upon which the tungsten-containing layer will be deposited will vary depending on the final use intended. In some embodiments, the substrate may be chosen from oxides which are used as dielectric materials in MIM, DRAM, or FeRam technologies (for example, ZrO₂ based materials, HfO₂ based materials, TiO₂ based materials, rare earth oxide based materials, ternary oxide based materials, etc.) or from nitride-based layers (for example, TaN) that are used as an oxygen barrier between copper and the low-k layer. Other substrates may be used in the manufacture of semiconductors, photovoltaics, LCD-TFT, or flat panel devices. Examples of such substrates include, but are not limited to, solid substrates such as copper and copper based alloys like CuMn, metal nitride-containing substrates (for example, TaN, TiN, WN, TaCN, TiCN, TaSiN, and TiSiN); insulators (for example, SiO₂, Si₃N₄, SiON, HfO₂, Ta₂O₅, ZrO₂, TiO₂, Al₂O₃, and barium strontium titanate); or other substrates that include any number of combinations of these materials. The actual substrate utilized may also depend upon the specific compound embodiment utilized. In many instances though, the preferred substrate utilized will be selected from Si and SiO₂ substrates.

The disclosed bis(alkylimido)-bis(alkylamido)tungsten compounds may be supplied either in neat form or in a blend with a suitable solvent, such as ethyl benzene, xylene, mesitylene, decane, dodecane, to form a precursor mixture. The disclosed compounds may be present in varying concentrations in the solvent.

One or more of the neat compounds or precursor mixtures are introduced into a reactor in vapor form by conventional means, such as tubing and/or flow meters. The vapor form of the neat compound or precursor mixture may be produced by vaporizing the neat compound or precursor mixture through a conventional vaporization step such as direct vaporization, distillation, by bubbling, or by using a sublimator such as the one disclosed in PCT Publication WO2009/087609 to Xu et al. The neat compound or precursor mixture may be fed in liquid state to a vaporizer where it is vaporized before it is introduced into the reactor. Alternatively, the neat compound or precursor mixture may be vaporized by passing a carrier gas into a container containing the neat compound or precursor mixture or by bubbling the carrier gas into the neat compound or precursor mixture. The carrier gas may include, but is not limited to, Ar, He, N₂, and mixtures thereof. The carrier gas and compound are then introduced into the reactor as a vapor.

If necessary, the container of the neat compound or precursor mixture may be heated to a temperature that permits the neat compound or precursor mixture to be in its liquid phase and to have a sufficient vapor pressure. The container may be maintained at temperatures in the range of, for example, approximately 0° C. to approximately 200° C. Those skilled in the art recognize that the temperature of the container may be adjusted in a known manner to control the amount of precursor vaporized.

In addition to the optional mixing of the bis(alkylimido)-bis(alkylamido) tungsten compound with solvents, second precursors, and stabilizers prior to introduction into the reactor, the bis(alkylimido)-bis(alkylamido) tungsten compound may be mixed with a reaction gas inside the reactor. Exemplary reaction gases include, without limitation, second precursors such as transition metal-containing precursors (eg. Niobium), rare earth-containing precursors, strontium-containing precursors, barium-containing precursors, aluminum-containing precursors such as TMA, and any combination thereof. These or other second precursors may be incorporated into the resultant layer in small quantities, as a dopant, or as a second or third metal in the resulting layer, such as WMO_{X}.

The reaction gas may include a reducing agent which is selected from, but not limited to, N₂, H₂, NH₃, SiH₄, Si₂H₆, Si₃H₈, (Me)₂SiH₂, (C₂H₅)₂SiH₂, (CH₃)₃SiH, (C₂H₅)₃SiH, [N(C₂H₅)₂]₂SiH₂, N(CH₃)₃, N(C₂H₅)₃, (SiMe₃)₂NH, (CH₃)HNNH₂, (CH₃)₂NNH₂, phenyl hydrazine, B₂H₆, (SiH₃)₃N, radical species of these reducing agents, and mixtures of these reducing agents. Preferably, when an ALD process is performed, the reducing reagent is H₂.

When the desired tungsten-containing layer also contains oxygen, such as, for example and without limitation, WOₓ and WMO_{X}, the reaction gas may include an oxidizing agent which is selected from, but not limited to, O₂, O₃, H₂O, H₂O₂, acetic acid, formalin, para-formaldehyde, radical species of these oxidizing agents, and mixtures of these oxidizing agents. Preferably, when an ALD process is performed, the oxidizing reagent is H₂O.

The reaction gas may be treated by plasma in order to decompose the reaction gas into its radical form. The plasma may be generated or present within the reaction chamber itself. Alternatively, the plasma may generally be at a location removed from the reaction chamber, for instance, in a remotely located plasma system. One of skill in the art will recognize methods and apparatus suitable for such plasma treatment.

For example, the reaction gas may be introduced into a direct plasma reactor, which generates plasma in the reaction chamber, to produce the plasma-treated reaction gas in the reaction chamber. Exemplary direct plasma reactors include the Titan™ PECVD System produced by Trion Technologies. The reaction gas may be introduced and held in the reaction chamber prior to plasma processing. Alternatively, the plasma processing may occur simultaneously with the introduction of the reaction gas. In-situ plasma is typically a 13.56 MHz RF capacitively coupled plasma that is generated between the showerhead and the substrate holder. The substrate or the showerhead may be the powered electrode depending on whether positive ion impact occurs. Typical applied powers in in-situ plasma generators are from approximately 30 W to approximately 1000 W. Preferably, powers from approximately 30 W to approximately 600 W are used in the disclosed methods. More preferably, the powers range from approximately 100 W to approximately 500 W. The disassociation of the reaction gas using in-situ plasma is typically less than achieved using a remote plasma source for the same power input and is therefore not as efficient in reaction gas disassociation as a remote plasma system, which may be beneficial for the deposition of tungsten-containing films on substrates easily damaged by plasma.

Alternatively, the plasma-treated reaction gas may be produced outside of the reaction chamber. The MKS Instruments' ASTRONi® reactive gas generator may be used to treat the reaction gas prior to passage into the reaction chamber. Operated at 2.45 GHz, 7 kW plasma power, and a pressure ranging from approximately 3 Torr to approximately 10 Torr, the reaction gas O₂ may be decomposed into two O⁻ radicals. Preferably, the remote plasma may be generated with a power ranging from about 1 kW to about 10 kW, more preferably from about 2.5 kW to about 7.5 kW.

When the desired tungsten-containing layer also contains another element, such as, for example and without limitation, Nb, Sr, Ba, Al, Ta, Hf, Nb, Mg, Y, Ca, As, Sb, Bi, Sn, Pb, Mn, lanthanides (such as Er), or combinations thereof, the reaction gas may include a second precursor which is selected from, but not limited to, metal alkyls, such as (Me)₃Al, metal amines, such as Nb(Cp)(NtBu)(NMe₂)₃, and any combination thereof.

The bis(alkylimido)-bis(alkylamido)tungsten compound and one or more reaction gases may be introduced into the reactor simultaneously (chemical vapor deposition), sequentially (atomic layer deposition), or in other combinations. For example, the bis(alkylimido)-bis(alkylamido)tungsten compound may be introduced in one pulse and two additional precursors may be introduced together in a separate pulse [modified atomic layer deposition]. Alternatively, the reactor may already contain the reaction gas prior to introduction of the bis(alkylimido)-bis(alkylamido)tungsten compound. Alternatively, the bis(alkylimido)-bis(alkylamido)tungsten compound may be introduced to the reactor continuously while other reaction gases are introduced by pulse (pulsed-chemical vapor deposition). The reaction gas may be passed through a plasma system localized or remotely from the reactor, and decomposed to radicals. In each example, a pulse may be followed by a purge or evacuation step to remove excess amounts of the component introduced. In each example, the pulse may last for a time period ranging from about 0.01 s to about 30 s, alternatively from about 0.3 s to about 3 s, alternatively from about 0.5 s to about 2 s. In another alternative, the bis(alkylimido)-bis(alkylamido)tungsten compound and one or more reaction gases may be simultaneously sprayed from a shower head under which a susceptor holding several wafers is spun (spatial ALD).

In one non-limiting exemplary atomic layer deposition type process, the vapor phase of a bis(alkylimido)-bis(alkylamido)tungsten compound is introduced into the reactor, where it is contacted with a suitable substrate. Excess bis(alkylimido)-bis(alkylamido)tungsten compound may then be removed from the reactor by purging and/or evacuating the reactor. An oxidizing reagent is introduced into the reactor where it reacts with the absorbed bis(alkylimido)-bis(alkylamido)tungsten compound in a self-limiting manner. Any excess oxidizing reagent is removed from the reactor by purging and/or evacuating the reactor. If the desired layer is a tungsten oxide layer, this two-step process may provide the desired layer thickness or may be repeated until a layer having the necessary thickness has been obtained.

Alternatively, if the desired WO layer contains a second element (i.e., WMO_{X}), the two-step process above may be followed by introduction of the vapor of a second precursor into the reactor. The second precursor will be selected based on the nature of the WMO_{X} layer being deposited. After introduction into the reactor, the second precursor is contacted with the substrate. Any excess second precursor is removed from the reactor by purging and/or evacuating the reactor. Once again, an oxidizing reagent may be introduced into the reactor to react with the second precursor. Excess oxidizing reagent is removed from the reactor by purging and/or evacuating the reactor. If a desired layer thickness has been achieved, the process may be terminated. However, if a thicker layer is desired, the entire four-step process may be repeated. By alternating the provision of the bis(alkylimido)-bis(alkylamido) tungsten compound, second precursor, and oxidizing reagent, a WMO_{X} layer of desired composition and thickness may be deposited.

Additionally, by varying the number of pulses, layers having a desired stoichiometric M:W ratio may be obtained. For example, a WMO₂ layer may be obtained by having one pulse of the bis(alkylimido)-bis(alkylamido) tungsten compound and one pulse of the second precursor, with each pulse being followed by pulses of the oxidizing reagent. However, one of ordinary skill in the art will recognize that the number of pulses required to obtain the desired layer may not be identical to the stoichiometric ratio of the resulting layer.

The tungsten-containing layers resulting from the processes discussed above may include pure tungsten (W), tungsten nitride (WₖNₗ), tungsten carbide (WₖCₗ), tungsten carbonitride (WₖCₗNₘ), tungsten silicide (WₙSiₘ), or tungsten oxide (WₙOₘ) film, wherein k, l, m, and n inclusively range from 1 to 6. Preferably, tungsten nitride and tungsten carbide are WₖNₗ or WₖCₗ, where k and l each range from 0.5 to 1.5. More preferably tungsten nitride is W₁N₁ and tungsten carbide is W₁C₁. Preferably tungsten oxide and tungsten silicide are WₙOₘ and WₙSiₘ, where n ranges from 0.5 to 1.5 and m ranges from 1.5 to 3.5. More preferably, tungsten oxide is WO₂ or WO₃ and tungsten silicide is WSi₂.

One of ordinary skill in the art will recognize that by judicial selection of the appropriate bis(alkylimido)-bis(alkylamido) tungsten compound and reaction gases, the desired W-containing layer composition may be obtained.

The W or WN films will have a resistivity ranging from 50 to 5000 μΩ·cm⁻¹, preferably from 50 to 1000 μΩ·cm⁻¹. The C content in the W or WN films will range from approximately 0.01 atomic % to approximately 10 atomic % for films deposited by thermal ALD and from approximately 0.01 atomic % to approximately 4 atomic % for films deposited by PEALD. The C content in the WO films will range from approximately 0.01 atomic % to approximately 2 atomic %.

Upon obtaining a desired film thickness, the film may be subject to further processing, such as thermal annealing, furnace-annealing, rapid thermal annealing, UV or e-beam curing, and/or plasma gas exposure. Those skilled in the art recognize the systems and methods utilized to perform these additional processing steps. For example, the tungsten-containing film may be exposed to a temperature ranging from approximately 200° C. to approximately 1000° C. for a time ranging from approximately 0.1 second to approximately 7200 seconds under an inert atmosphere, a H-containing atmosphere, a N-containing atmosphere, an O-containing atmosphere, or combinations thereof. Most preferably, the temperature is 400° C. for 3600 seconds under a H-containing atmosphere. The resulting film may contain fewer impurities and therefore may have an improved density resulting in improved leakage current. The annealing step may be performed in the same reaction chamber in which the deposition process is performed. Alternatively, the substrate may be removed from the reaction chamber, with the annealing/flash annealing process being performed in a separate apparatus. Any of the above post-treatment methods, but especially thermal annealing, is expected to effectively reduce any carbon and nitrogen contamination of the tungsten-containing film. This in turn is expected to improve the resistivity of the film. The resistivity of the WN film after post-treatment may range from approximately from 50 to 1000 μΩ·cm⁻¹.

In another alternative, the disclosed bis(alkylimido)-bis(alkylamido) tungsten compounds may be used as doping or implantation agents. Part of the disclosed bis(alkylimido)-bis(alkylamido) tungsten compound may be deposited on top of the film to be doped, such as an indium oxide (In₂O₃) film, vanadium dioxide (VO₂) film, a titanium oxide film, a copper oxide film, or a tin dioxide (SnO₂) film. The tungsten then diffuses into the film during an annealing step to form the tungsten-doped films {(W)In₂O₃, (W)VO₂, (W)TiO, (W)CuO, or (W)SnO₂}. See, e.g., US2008/0241575 to Lavoie et al., the doping method of which is incorporated herein by reference in its entirety. Alternatively, high energy ion implantation using a variable energy radio frequency quadrupole implanter may be used to dope the tungsten of the bis(alkylimido)-bis(alkylamido) tungsten compound into a film. See, e.g., Kensuke et al., JVSTA 16(2) March/April 1998, the implantation method of which is incorporated herein by reference in its entirety. In another alternative, plasma doping, pulsed plasma doping or plasma immersion ion implantation may be performed using the disclosed bis(alkylimido)-bis(alkylamido) tungsten compounds. See, e.g., Felch et al., Plasma doping for the fabrication of ultra-shallow junctions Surface Coatings Technology, 156 (1-3) 2002, pp. 229-236, the doping method of which is incorporated herein by reference in its entirety.

### EXAMPLES

The following non-limiting examples are provided to further illustrate embodiments of the invention. However, the examples are not intended to be all inclusive and are not intended to limit the scope of the inventions described herein.

### Example 1

### Synthesis of W(NtBu)₂(NHtBu)₂

W(NtBu)₂(NHtBu)₂ was synthesized by the method described by Nugent et al. (Inorganic Chemistry (1980) 19(3), 777-9).

W(NtBu)₂(NMe₂)₂ was commercially purchased.

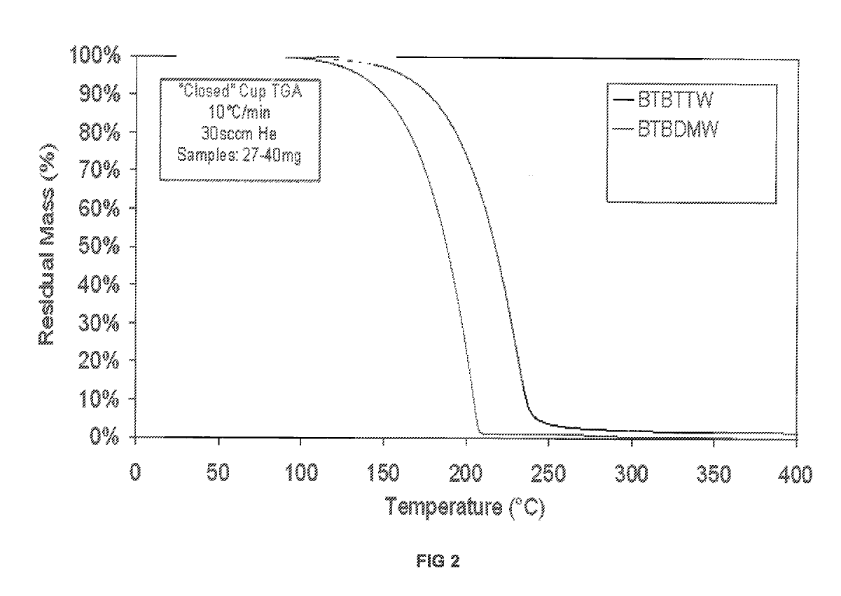

The closed cup TGA results for both molecules are shown in FIG. 2. W(NtBu)₂(NHtBu)₂ may be vaporized at high temperature without a substantial amount of residue.

### Example 2 (Prophetic)

### Deposition Using W(NtBu)₂(NHtBu)₂ and Ammonia

W(NtBu)₂(NHtBu)₂ will be used for deposition of WN films in ALD mode using ammonia as a co-reactant. The tungsten molecule will be heated in a canister, and its vapors will be provided to the reaction furnace by N₂, He or Ar bubbling method. The lines will be heated to prevent condensation. The delivery set-up will enable alternate introductions of the vapors of the tungsten precursor and of ammonia. Tungsten nitride films are expected to be obtained up to a temperature of 425° C. Saturation mode characteristic of ALD is expected to be obtained at a temperature around 350° C. to 400° C., as the increase of the pulse time of the precursor is not expected to impact the growth rate of the WN film at those temperatures. Good linearity of film growth is expected to be obtained as a function of number of cycles. Highly conformal film growth characterized by scanning electron microscopy (SEM) will indicate that the high stability of the molecule is beneficial to good step coverage.

The composition of the films will be analyzed by XPS and are expected to be stoichiometric WN. A low concentration of C and O, standard impurities in metal nitride films, will indicate the good quality of the film. The good quality of the film will further be confirmed by the low resistivity of the WN films. The resistivity of the WN films are measured within a large window of deposition temperature. It should be observed that the higher the deposition temperature, the lower the resistivity of the films. This result will prove the benefit of high temperature ALD process enable by the use of the family of stable molecules described in this document.

Counter Example from Literature:

Becker et al. performed ALD evaluation of W(NtBu)₂(NMe₂)₂ with NH₃ (Chem. Mater. 2003, 15, 2969). WN films were obtained between 250° C. and 350° C., but the thicknesses of the films increased with increasing deposition temperature. Id. Films were formed at temperatures above 350° C., but they contained carbon and their step coverage was not as good as that for the films made at lower temperatures. Id. Thus decomposition is believed to be triggered between 325° C. and 350° C. Precursor decomposition apparently becomes significant above 350° C. Id.

The deposition temperature of this process is thus much lower than the one that is expected to be obtained with the process described in Example 1. As discussed in detail supra, an increase in deposition temperature is believed to produce films having better film qualities.

### Example 3 (Prophetic)

### WO₃ Deposition

The same precursor as in Example 2 will be used, but NH₃ will be replaced by ozone (O₃). The same ALD introduction scheme will be used. Saturation is expected to be obtained at 400° C. Composition analyses is expected to confirm that the obtained films are WO₃ and that the carbon content in the films is low (0-2 atomic %).

### Example 4 (Prophetic)

### PEALD WN Deposition

The same precursor as in Example 2 will be used with NH₃ and provided to the reaction chamber in an ALD mode scheme. In this case, a plasma source will be switched on during the NH₃ pulse. The use of plasma may provide the ability to decrease the concentration of carbon and oxygen impurities in the film. As a result, film resistivity may also be lowered.

### Example 5 (Prophetic)

### PEALD W Deposition

The same precursor as in Example 2 will be used with H₂ and provided to the reaction chamber in an ALD mode scheme. In this case, a plasma source will be switched on during the H₂ pulse. The use of plasma may provide the ability to decrease the concentration of carbon and oxygen impurities in the film. As a result, film resistivity may also be lowered.

Film composition data is expected to show that the levels of nitrogen, carbon, and oxygen concentration are <5% each. As the metallic tungsten film is expected to be of high purity, the resistivity of the films will be very low, making this film very interesting candidates for metallic coatings.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

1. An atomic layer deposition method for forming a tungsten-containing film on a substrate, the method comprising:
introducing a tungsten-containing precursor into a vapor deposition chamber containing a substrate, the tungsten-containing precursor having the formula W(NR)₂(NHR′)₂, wherein R and R′ are independently chosen from the group consisting of a C1-C4 alkyl group, a C1-C4 perfluoroalkyl group, and an alkylsilyl group; and
depositing at least part of the tungsten-containing precursor on the substrate by atomic layer deposition to form a tungsten-containing film.

2. The atomic layer deposition method of claim 1, wherein the tungsten-containing precursor is selected from the group consisting of W(NMe)₂(NHMe)₂, W(NMe)₂(NHEt)₂, W(NMe)₂(NHPr)₂, W(NMe)₂(NHiPr)₂, W(NMe)₂(NHBu)₂, W(NMe)₂(NHiBu)₂, W(NMe)₂(NHsBu)₂, W(NMe)₂(NHtBu)₂, W(NEt)₂(NHMe)₂, W(NEt)₂(NHEt)₂, W(NEt)₂(NHPr)₂, W(NEt)₂(NHiPr)₂, W(NEt)₂(NHBu)₂, W(NEt)₂(NHiBu)₂, W(NEt)₂(NHsBu)₂, W(NEt)₂(NHtBu)₂, W(NPr)₂(NHMe)₂, W(NPr)₂(NHEt)₂, W(NPr)₂(NHPr)₂, W(NPr)₂(NHiPr)₂, W(NPr)₂(NHBu)₂, W(NPr)₂(NHiBu)₂, W(NPr)₂(NHsBu)₂, W(NPr)₂(NHtBu)₂, W(NiPr)₂(NHMe)₂, W(NiPr)₂(NHEt)₂, W(NiPr)₂(NHPr)₂, W(NiPr)₂(NHiPr)₂, W(NiPr)₂(NHBu)₂, W(NiPr)₂(NHiBu)₂, W(NiPr)₂(NHsBu)₂, W(NiPr)₂(NHtBu)₂, W(NBu)₂(NHMe)₂, W(NBu)₂(NHEt)₂, W(NBu)₂(NHPr)₂, W(NBu)₂(NHiPr)₂, W(NBu)₂(NHBu)₂, W(NBu)₂(NHiBu)₂, W(NBu)₂(NHsBu)₂, W(NBu)₂(NHtBu)₂, W(NiBu)₂(NHMe)₂, W(NiBu)₂(NHEt)₂, W(NiBu)₂(NHPr)₂, W(NiBu)₂(NHiPr)₂, W(NiBu)₂(NHBu)₂, W(NiBu)₂(NHiBu)₂, W(NiBu)₂(NHsBu)₂, W(NiBu)₂(NHtBu)₂, W(NsBu)₂(NHMe)₂, W(NsBu)₂(NHEt)₂, W(NsBu)₂(NHPr)₂, W(NsBu)₂(NHiPr)₂, W(NsBu)₂(NHBu)₂, W(NsBu)₂(NHiBu)₂, W(NsBu)₂(NHsBu)₂, W(NsBu)₂(NHtBu)₂, W(NtBu)₂(NHMe)₂, W(NtBu)₂(NHEt)₂, W(NtBu)₂(NHPr)₂, W(NtBu)₂(NHiPr)₂, W(NtBu)₂(NHBu)₂, W(NtBu)₂(NHiBu)₂, W(NtBu)₂(NHsBu)₂, W(NtBu)₂(NHtBu)₂, W(NSiMe₃)₂(NHMe)₂, W(NSiMe₃)₂(NHEt)₂, W(NSiMe₃)₂(NHPr)₂, W(NSiMe₃)₂(NHiPr)₂, W(NSiMe₃)₂(NHBu)₂, W(NSiMe₃)₂(NHiBu)₂, W(NSiMe₃)₂(NHsBu)₂, W(NSiMe₃)₂(NHtBu)₂, W(NCF₃)₂(NHMe)₂, W(NCF₃)₂(NHEt)₂, W(NCF₃)₂(NHPr)₂, W(NCF₃)₂(NHiPr)₂, W(NCF₃)₂(NHBu)₂, W(NCF₃)₂(NHiBu)₂, W(NCF₃)₂(NHsBu)₂, W(NCF₃)₂(NHtBu)₂, W(NMe)₂(NHSiMe₃)₂, W(NEt)₂(NHSiMe₃)₂, W(NPr)₂(NHSiMe₃)₂, W(NtBu)₂(NHSiMe₃)₂, W(NtAmyl)₂(NHiPr)₂, W(NtAmyl)₂(NHBu)₂, W(NtAmyl)₂(NHiBu)₂, W(NtAmyl)₂(NHsBu)₂, W(NtAmyl)₂(NHtBu)₂, W(NtAmyl)₂(NHSiMe₃)₂, and W(NtBu)(NtAmyl)(NHtBu)₂, preferably W(NtBu)₂(NHiPr)₂, W(NtBu)₂(NHtBu)₂, W(NtAmyl)₂(NHiPr)₂, and W(NtAmyl)₂(NHtBu)₂.

3. The atomic layer deposition method of claim 2, wherein the at least part of the tungsten-containing precursor is deposited on the substrate by plasma enhanced atomic layer deposition.

4. The atomic layer deposition method of claim 3, wherein a plasma power is between about 30 W and about 600 W, preferably between about 100 W and about 500 W

5. The atomic layer deposition method of claim 1, further comprising reacting the at least part of the tungsten-containing precursor with a reducing agent.

6. The atomic layer deposition method of claim 5, wherein the reducing agent is selected from the group consisting of N₂, H₂, NH₃, N₂H₄ and any hydrazine based compounds, SiH₄, Si₂H₆, radical species thereof, and combinations thereof.

7. The atomic layer deposition method of claim 1, further comprising reacting the at least part of the tungsten-containing precursor with an oxidizing agent.

8. The atomic layer deposition method of claim 7, wherein the oxidizing agent is selected from the group consisting of O₂, H₂O, O₃, H₂O₂, N₂O, NO, acetic acid, the radical species thereof, and combinations thereof.

9. The atomic layer deposition method of claim 1, wherein the method is performed at a pressure between about 0.01 Pa and about 1×10⁵ Pa, preferably between about 0.1 Pa and about 1×10⁴ Pa.

10. The atomic layer deposition method of claim 1, wherein the method is performed at a temperature between about 20° C. and about 500° C., preferably between about 350° C. and about 500° C.
